(19) United States
(12) Patent Application Publication
(10) Pub. No.: US 2014/0338722 A1
(43) Pub. Date: Nov. 20, 2014

(54) PHOTOVOLTAIC MODULES WITH A CONTROLLED COLOR ON THEIR WINDOW SURFACE AND ARRAYS THEREOF

(71) Applicant: First Solar, Inc., Tempe, AZ (US)

(72) Inventors: Scott Daniel Feldman-Peabody, Golden, CO (US); Robert Andrew Garber, Denver, CO (US); Douglas Garth Jensen, Lakewood, CO (US)

(73) Assignee: First Solar, Inc., Tempe, AZ (US)

(21) Appl. No.: 13/893,494

(22) Filed: May 14, 2013

(51) Int. Cl. H01L 31/0216; H01L 31/18; H01L 31/042

(52) U.S. Cl. CPC H01L 31/02167; H02S 30/00; H01L 31/1876
USPC 136/246; 136/256; 438/72

(57) ABSTRACT

Thin film photovoltaic devices are provided that include a transparent substrate defining an inner surface and an outer surface; a thin film stack on the inner surface of the transparent substrate; an encapsulation substrate on the thin film stack; and a color reflection film on the outer surface of the transparent substrate. The thin film stack has a photovoltaic heterojunction (e.g., formed from a n-type window thin film layer and an absorber thin film layer). Generally, the color reflection film comprises a colorant, such as a refractive material (e.g., a nitride material, an oxide material, or mixtures thereof). Methods are also provided for forming such a photovoltaic device, and for forming an array of photovoltaic devices to define an image.

### FIELD OF THE INVENTION

The subject matter disclosed herein relates generally to photovoltaic modules having a controlled color on their window surface, and their methods of production.

### BACKGROUND OF THE INVENTION

Thin film photovoltaic (PV) modules (also referred to as “solar panels”) are gaining wide acceptance and interest in the industry. Each PV module generally has a very dark visual appearance. For instance, thin film PV modules (e.g., based on thin films of CIS, CIGS, CIGSSe, CdTe, etc. as the absorber layer) generally have a dark blue or near black appearance. It would be desirable, however, to control the color of the PV device to allow for controlling the appearance of the individual module and/or the array of modules without sacrificing the efficiency of each PV device.

### BRIEF DESCRIPTION OF THE INVENTION

Aspects and advantages of the invention will be set forth in part in the following description, or may be obvious from the description, or may be learned through practice of the invention.

Thin film photovoltaic devices are generally provided that can include, in one embodiment, a transparent substrate defining an inner surface and an outer surface; a thin film stack on the inner surface of the transparent substrate; an encapsulation substrate on the thin film stack; and a color reflection film on the outer surface of the transparent substrate. The thin film stack generally has a photovoltaic heterojunction (e.g., formed from a n-type window thin film layer and an absorber thin film layer). Generally, the color reflection film comprises a colorant, such as a refractive material (e.g., a nitride material, an oxide material, or mixtures thereof).

Methods are also generally provided for forming such a photovoltaic device, and for forming an array of photovoltaic devices to define an image.

In one embodiment, for instance, a method is generally disclosed for forming an image on an array of photovoltaic modules. This method can include creating a digital image on a computing device, and overlaying the digital image on a digital representation of a solar array to generate an image map. The digital representation of the solar array generally includes a plurality of array segments that each correspond to an individual photovoltaic device. A color reflection film can then be formed on an outer surface of the individual photovoltaic devices using the image map such that the color reflection film on each individual photovoltaic device corresponds to one of the array segments of the digital representation of the solar array. Finally, the individual photovoltaic devices can be arranged into an array such that the image is formed by the collective photovoltaic devices.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 shows a general schematic of a cross-sectional view of an exemplary thin film photovoltaic device;

FIG. 2 shows a general schematic of a cross-sectional view of another exemplary thin film photovoltaic device;

FIG. 3 shows a general schematic of a cross-sectional view of yet another exemplary thin film photovoltaic device;

FIGS. 4A-4E sequentially show an exemplary method of forming a pattern on the outer surface with the color reflective layer;

FIG. 5 shows an exemplary solar array formed from a plurality of photovoltaic devices;

FIG. 6 shows another exemplary solar array formed from a plurality of photovoltaic devices; and,

FIG. 7 shows a block diagram of an exemplary computing device that can be used to implement methods and systems according to exemplary embodiments of the present disclosure.

Repeat use of reference characters in the present specification and drawings is intended to represent the same or analogous features or elements.

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

In the present disclosure, when a layer is being described as “on” or “over” another layer or substrate, it is to be understood that the layers can either be directly contacting each other or have another layer or feature between the layers. Thus, these terms are simply describing the relative position of the layers to each other and do not necessarily mean “on top of” since the relative position above or below depends upon the orientation of the device to the viewer. Additionally, although the invention is not limited to any particular film thickness, the term “thin” describing any film layers of the photovoltaic device generally refers to the film layer having a thickness less than about 10 micrometers (“microns” or “μm”).

It is to be understood that the ranges and limits mentioned herein include all ranges located within the prescribed limits (i.e., subranges). For instance, a range from about 100 to about 200 also includes ranges from 110 to 150, 170 to 190, 153 to 162, and 145.3 to 149.6. Further, a limit of up to about 7 also includes a limit of up to about 5, up to 3, and up to about 4.5, as well as ranges within the limit, such as from about 1 to about 5, and from about 3.2 to about 6.5.

Chemical elements are discussed in the present disclosure using their common chemical abbreviation, such as commonly found on a periodic table of elements. For example, hydrogen is represented by its common chemical abbreviation H; helium is represented by its common chemical abbreviation He; and so forth.

Thin film photovoltaic devices are generally provided that have a color reflection film on at least a portion of the outer surface of the transparent substrate. The color reflection film includes a transparent material having a refractive index that changes the perceived color of the face of the module. Color reflection films having different index materials deposited on the outer surfaces of the transparent substrate (e.g., a glass substrate) can produce different color reflections. When an array of such modules is formed, modules within the array can have a color reflection film of varying refractive indexes on their respective outer surfaces in order to form an image (e.g., logos, advertisements, alphanumeric characters, pictures, etc.) in the array. For example, when included within a very large array, individual modules can form pixels of a large picture. Alternatively, in smaller arrays, the outer surface(s) of the transparent substrate of individual modules can be patterned one or more color reflection film on its surface (e.g., via a masking method). In this way, an array or field of modules can act as advertisement in addition to producing power.

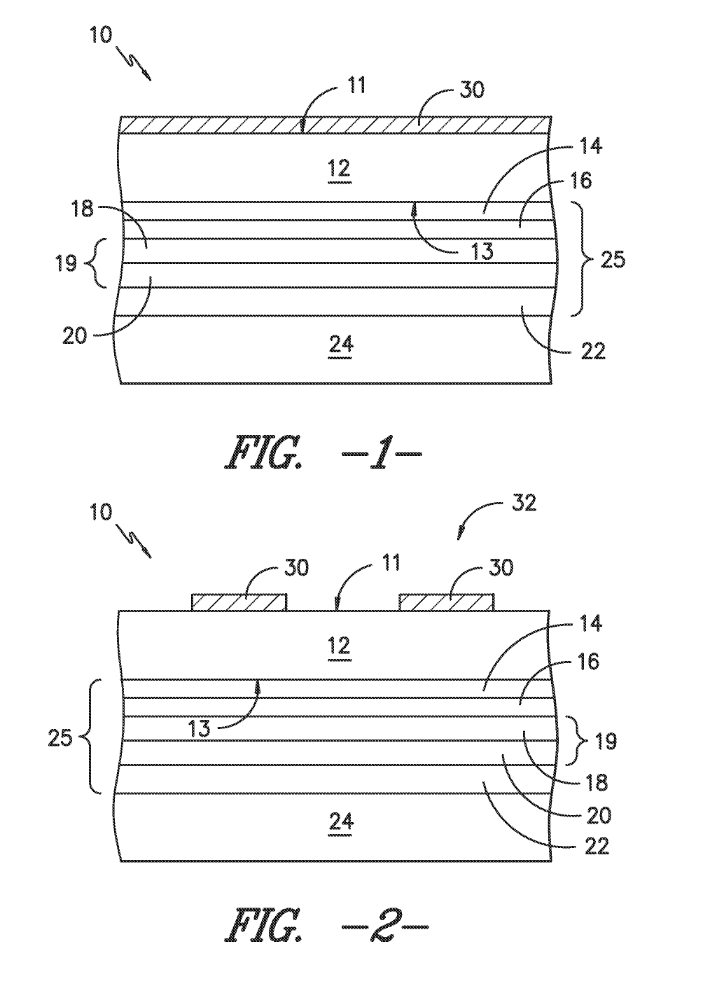

Referring to FIG. 1, a thin film photovoltaic device 10 is shown that includes a transparent substrate 12, a thin film stack 25 on an inner surface 13 of the transparent substrate 12; and an encapsulation substrate 24 on the thin film stack 25. A color reflection film 30 is positioned on an outer surface 11 of the transparent substrate 12.

Generally, the color reflection film 30 includes an high transmission material that has a refractive index that is higher or lower relative to the refractive index of the transparent substrate 12. In one embodiment, the color reflective film 30 includes a colorant (e.g., a refractive material, a pigment, a dye, etc.) on the outer surface 11 of the transparent substrate 12 in a manner that allows a majority of light to pass through the color reflective film 30 into the device 10. By controlling the thickness of the color reflection film 30, the selection of the colorant (i.e., the refractive index of the colorant), and/or the concentration of the colorant present on the outer surface 11 of the transparent substrate 12, different colors can be achieved on the outer surface 11 of the device 10. For instance, the color reflective film 30 can allow at least about 95% of electromagnetic radiation in the visible spectrum (e.g., wavelengths from about 390 to about 700 nm) to pass through the film 30 and into the device 10, such as about 98% to about 99.99%. Thus, the amount of electromagnetic radiation that reaches the underlying thin film stack 25 is not substantially impaired by the presence of the color reflective thin film 30 on the outer surface 11 of the transparent substrate 12.

In one embodiment, a refractive material can be included in the color reflective thin film 30, including but not limited to, nitride materials (e.g., Si₃N₄, etc.), oxide materials (e.g., TiO₂, etc.), or mixtures thereof. However, any other material with an index of refraction different than (e.g., greater than or lower than) that of the transparent substrate 12 could, in principle, be used.

Such refractive materials can be dispersed on the outer surface 11 of the transparent substrate 12 in a concentration that allows at least about 95% of electromagnetic radiation in the visible spectrum (e.g., wavelengths from about 390 to about 700 nm) to pass through the color reflective thin film 30 and into the device 10, such as about 98% to about 99.99%.

In one particular embodiment, the refractive material can be deposited as a thin film as the color reflective layer 30 onto the outer surface 11 of the transparent substrate 12. The refractive material can be deposited alone (i.e., as a sole component of the thin film) or can be dispersed within a transparent medium (e.g., a transparent oxide). For example, the color reflective layer 30 containing the refractive material can be deposited via sputtering, sublimation, chemical vapor deposition, spray deposition, roll coating chemical bath deposition, or other deposition methods. The thickness of the color reflective film 30 can be deposited to be up to about 5 μm, such as about 10 nm to about 1 μm (e.g., about 50 nm to about 500 nm). With these relatively small thicknesses of the color reflective film 30, deposited as a thin film, the electromagnetic radiation in the visible spectrum can readily pass through the color reflective thin film 30 and into the device 10 for conversion to electric energy without any substantial effect on the device 10's efficiency.

The thickness of the color reflective layer 30 can also be varied depending on the concentration of the refractive material within the color reflective film 30. For example, when deposited as a thin film layer without any other materials present (i.e., the color reflective film 30 consists essentially of the refractive material), the thickness of the thin film layer can be relatively small, such as about 10 nm to about 100 nm. However, when deposited as a thin film where the refractive material is dispersed within a transparent medium, the color reflective film 30 can be somewhat thicker due to the dilution of the refractive material within the color reflective film 30 while not substantially affecting the amount of light entering the device 10, such as about 50 nm to about 5 μm. In one embodiment, the transparent medium can include a transparent oxide, including but not limited to, such as tin oxide, zinc oxide, SiO₂, or mixtures thereof.

Alternatively, the colorant (e.g., a refractive material, a pigment, and/or dye) can be dispersed within a transparent polymeric binder. For example, the colorant can be dispersed within a polymeric binder material and then coated on the outer surface 11 of the transparent substrate 12. The transparent polymeric binder can include, but is not limited to, a polyolefin material (e.g., polyethylene, polypropylene, etc.), a polyurethane, a polyester, a polyethylene terephthalate (PET), a (meth)acrylic resin, an epoxy resin, etc.

Such a polymeric layer can be coated utilizing known coating techniques, such as by roll, blade, Meyer rod, air-knife coating procedures, extrusion coating, etc. The color reflective film 30 containing a polymeric material can have, in particular embodiments, a thickness of about 1 μm to about 1 mm.

No matter the composition or method of formation/deposition, the color reflective film 30 can be formed in a substantially uniform manner on the outer surface 11 of the transparent substrate 12. Multiple devices 10 can be positioned within an array to form a pattern, if desired. Such an array can be formed from devices 10 having different color reflective films that appear different (e.g., having different colorants) to define a pattern within the array.

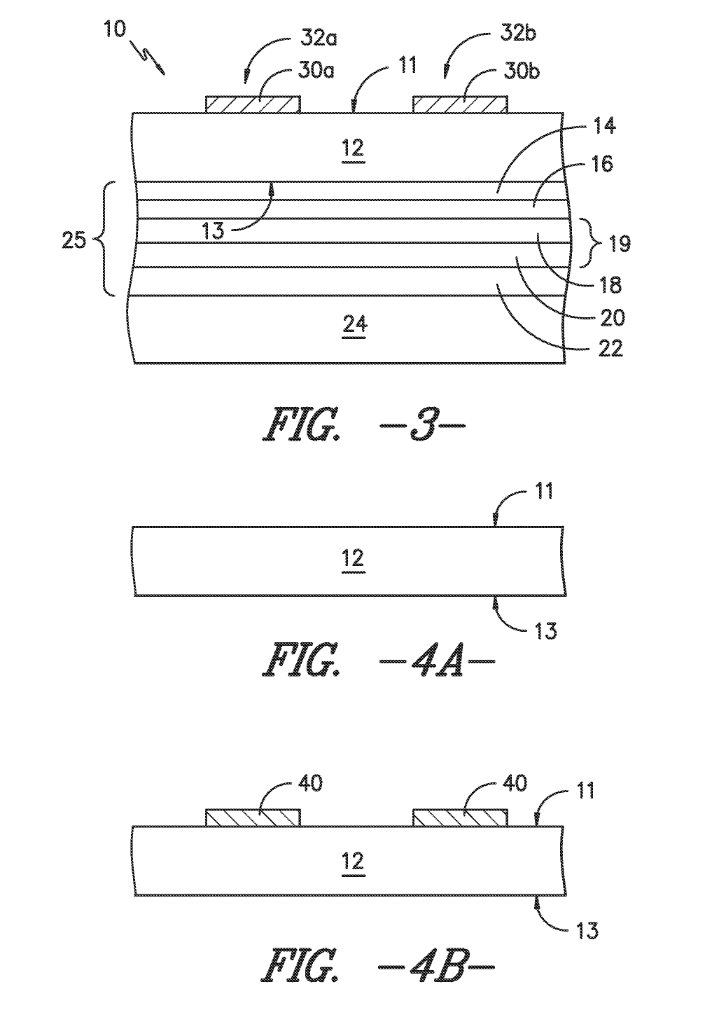

Alternatively, as shown in FIG. 2, the color reflective film 30 may define a pattern 32 on the outer surface 11 of the transparent substrate 12. The pattern 32 can be formed via any suitable method. In one particular embodiment, the pattern 32 can be formed by first masking a portion(s) of the outer surface to prevent the color reflective film from depositing on those masked portions.

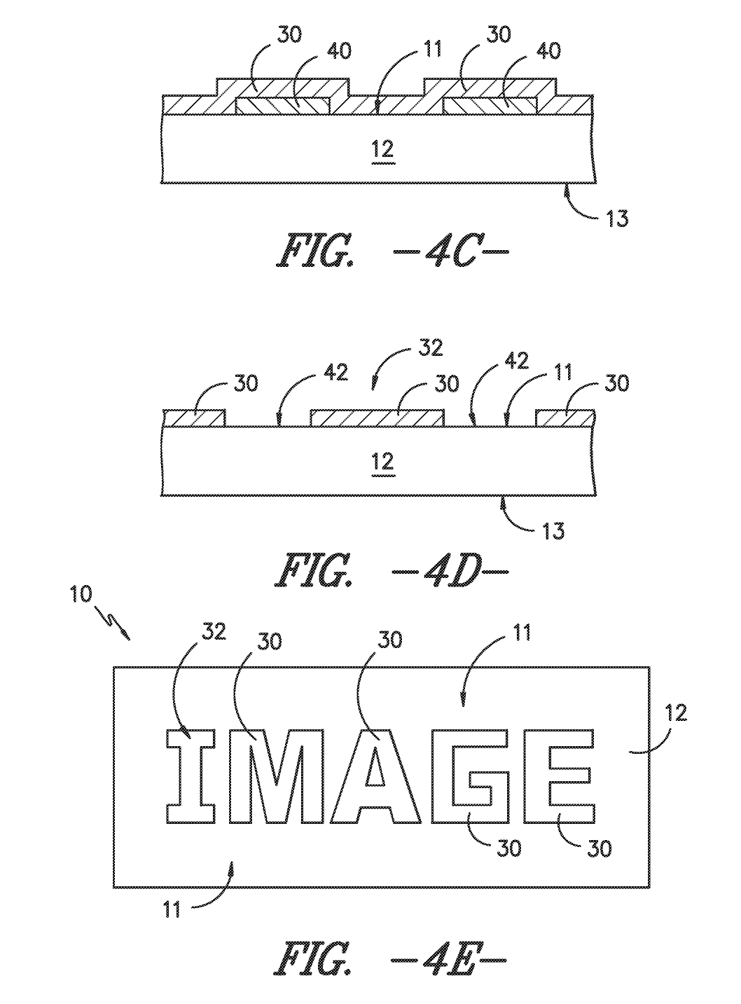

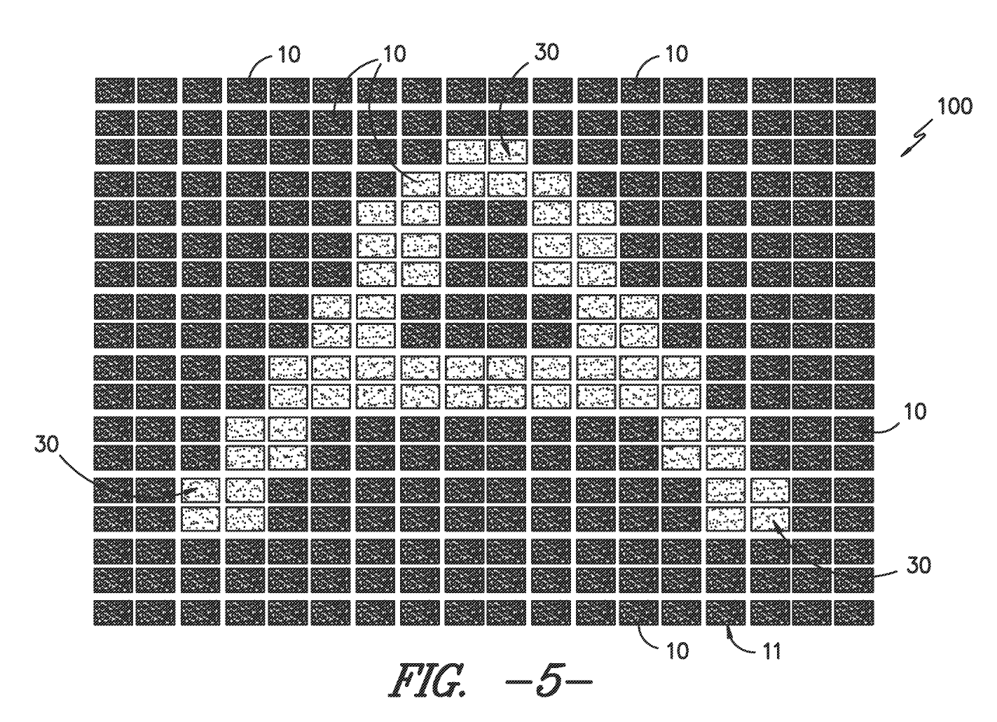

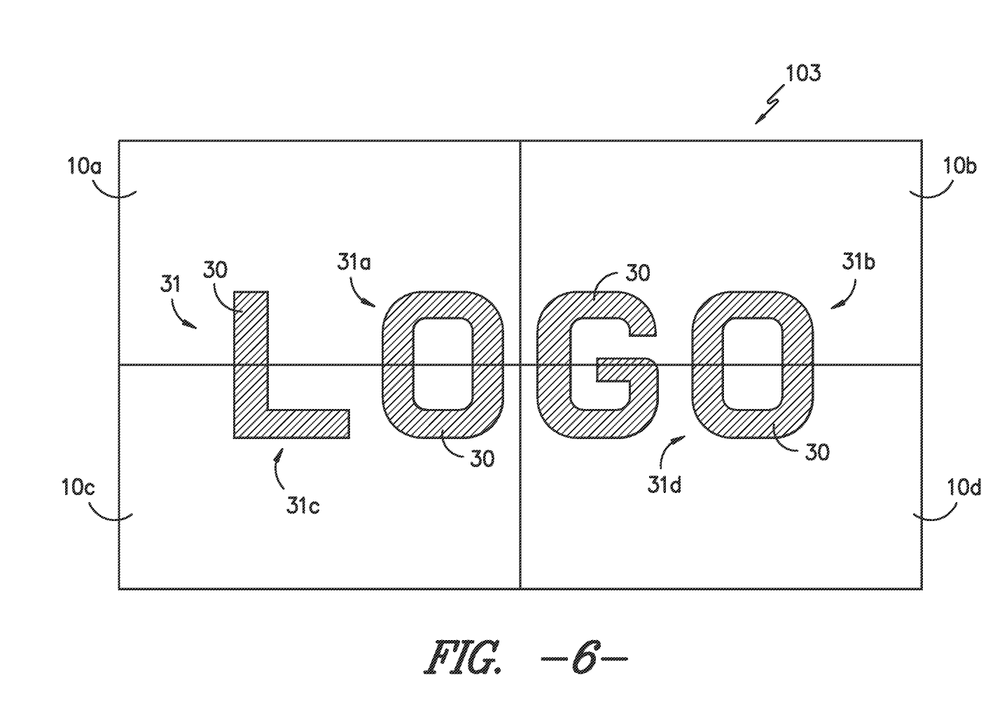

Referring to FIGS. 4A-4E, masking can be achieved, for example, using a photoresist method or a tape method (e.g., kapton tape). In either of these embodiments, for example, the mask 40 (e.g., a layer of photoresist or tape, or a stencil, etc.) is first applied onto the outer surface 11 of the transparent substrate 12, as shown in FIG. 4B. The locations of the mask 40 on the outer surface 11 will correspond to the negative image formed by the subsequent pattern 32.

Then, the color reflective film 30 is applied/deposited onto the outer surface 11 and over the mask 40, as shown in FIG. 4C. Following formation of the color reflective film 30, the masking material 40 is removed (along with any color reflective film 30 thereon) to expose the underlying outer surface 11 of the transparent substrate 12, as shown in FIG. 4D. Thus, a pattern 32 can be defined by color reflective film 30 on the outer surface 11, with areas 42 corresponding to the previous location of the mask 40 that are substantially free from any color reflective film material. As shown in FIG. 4E, the pattern 42 can be controlled as desired, and can include for example alphanumeric characters (as shown), designs, logos, pictures, etc.

In the embodiment of FIG. 3, multiple layers such color reflective films 30a, 30b (e.g., where each color reflective film 30a, 30b has a different refractive index) can be applied onto the outer surface 11 of the transparent substrate 12. For example, a first color reflective film 30a can define a first pattern 32a, a second color reflective film 30b can define a second pattern 32b, and so on. In this manner, the visible pattern 32 on the outer surface 11 of the device 10 can be perceived to have multiple colors.

In one embodiment, such as shown in FIG. 5, a solar array 100 can be formed by arranging a plurality of individual photovoltaic devices 10 adjacent to one another. In this embodiment, the image can be defined by a color reflective film 30 (or plurality of films) on at least a portion of the outer surface 11 of at least a portion of the devices 10. In the exemplary array 100 shown in FIG. 5, the devices 10 having a color reflective film 30 thereon define the image in a pixilated pattern in the array 100.

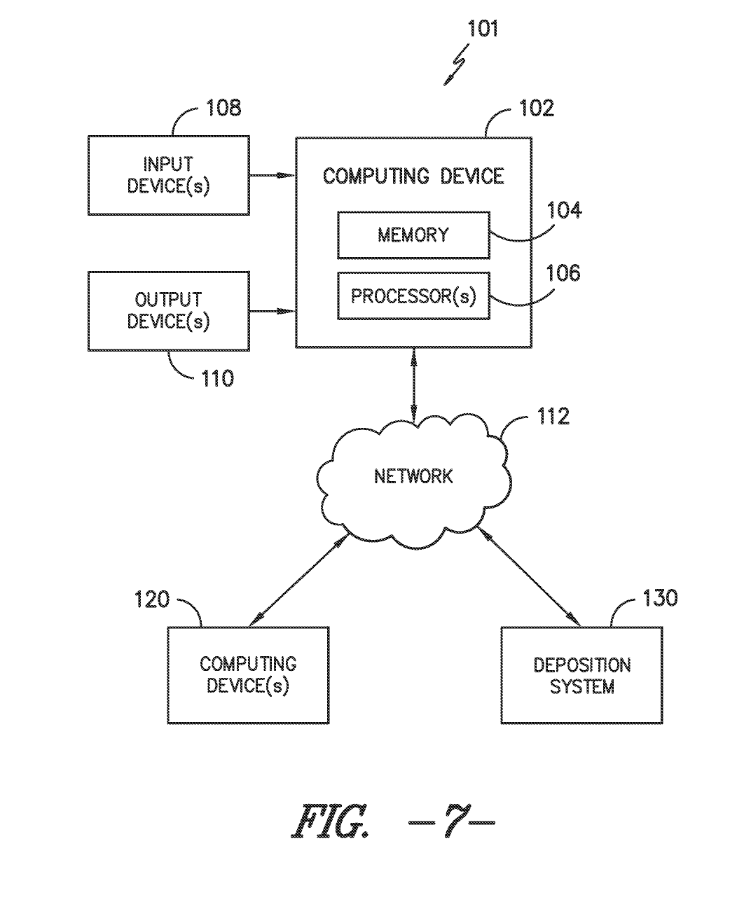

Referring to FIG. 6, an exemplary array 103 is shown having a plurality of photovoltaic devices 10a-10d arranged adjacent to each other. In this embodiment, the image 31 is formed from the color reflective film 30 deposited on a portion of each of the devices 10. As shown, a first portion 31a of the color reflective film 30 is located on the first device 10a; a second portion 31b of the color reflective film 30 is located on the second device 10b; a third portion 31c of the color reflective film 30 is located on the third device 10c; and a fourth portion 31d of the color reflective film 30 is located on the fourth device 10d. The devices 10a-10d are arranged adjacent to one another to form collectively the image 31 when in the array 103. Although shown comprising four devices 10, the array 103 can include any number of devices 10 with any image 31 thereon.

FIG. 7 shows a block diagram of an exemplary computer based system 100 that can be used to form such an array 100, 103 as in FIG. 5 or 6. Generally, the computer based system 100 can include one or more general-purpose or customized computing devices adapted in any suitable manner to provided desired functionality. Computer based system 100 may be adapted to provide additional functionality complementary or unrelated to the present subject matter as well. As illustrated, computer-based system 100 can include a computing device 102 having a memory 104 and a processor 106. Memory 104 can be provided as a single or multiple portions of one or more varieties of computer-readable media, such as but not limited to any combination of volatile memory (e.g., random access memory (RAM, such as DRAM, SRAM, etc.) and nonvolatile memory (e.g., ROM, flash, hard drives, magnetic tapes, CD-ROM, DVD-ROM, etc.) or any other memory devices including diskettes, drives, other magnetic-based storage media, optical storage media, solid state storage media and others.

Processor 106 can be a microprocessor or other suitable processing device configured to execute software instructions rendered in a computer-readable form stored in memory 104. When software is used, any suitable programming, scripting, or other type of language or combinations of languages may be used to implement the teachings contained herein. In other embodiments, the methods disclosed herein may alternatively be implemented by hard-wired logic or other circuitry, including, but not limited to application-specific circuits.

As illustrated computing device 102 can be coupled to input device(s) 108 and output device(s) 110. Exemplary input device(s) 108 can include but are not limited to a keyboard, touch-screen monitor, eye tracker, microphone, mouse and the like. Exemplary output device(s) 110 can include but are not limited to monitors, printers or other devices for visually depicting output data created in accordance with the disclosed technology.

Computing device 102 can be optionally connected to other computing devices 120 over network 112. Network 112 can be comprise any number and/or combination of hard-wired, wireless, or other communication links. One of ordinary skill in the art will recognize that the inherent flexibility of computer-based systems allows for a great variety of possible configurations, combinations, and divisions of tasks and functionality between and among components. For instance, the processes discussed herein may be implemented using single computing device 102 or across multiple computing devices, such as computing device 102 and computing device(s) 120 working in combination. Computing device 102 can also be coupled to deposition system 130 over network 112. Computer based system 100 can send and receive information and data from the actual deposition system 130 (form forming, e.g., the color reflective film 30 on a device 10) for use by imaging software stored in memory 104 of computing device 102.

For example, a digital image can be created on a computing device 102 and overlaid on a digital representation of a solar array to generate an image map. Generally, the digital representation of the solar array comprises a plurality of array segments that each correspond to an individual photovoltaic device 10. A color reflection film 30 can then be formed on an outer surface of the individual photovoltaic devices using the image map such that the color reflection film 30 on each individual photovoltaic device 10 corresponds to one of the array segments of the digital representation of the solar array. Finally, the individual photovoltaic devices 10 can be arranged into an array 100, 103 such that the image 31 is formed by the collective photovoltaic devices 10.

Referring to FIG. 6, for instance, the first portion 31a of the image 31 is formed by depositing a color reflective film 30 over a portion of the first device 10a according to the image map; the second portion 31b of the image 31 is formed by depositing a color reflective film 30 over a portion of the second device 10b according to the image map; the third portion 31c of the image 31 is formed by depositing a color reflective film 30 over a portion of the third device 10c according to the image map; and the fourth portion 31d of the image 31 is formed by depositing a color reflective film 30 over a portion of the fourth device 10d according to the image map. The devices 10a-10d are arranged adjacent to one another to form collectively the image 31 when in the array 103.

As stated, the device 10 shown in FIG. 1 includes a transparent substrate 12 (e.g., a glass substrate) and an encapsulation substrate 25 (e.g., a glass substrate) with a thin film stack 25 positioned therebetween. Although discussed below with respect to a cadmium telluride based thin film photovoltaic device 10, it is understood that the following discussion is not intended to limit the scope of the present disclosure.

In one particular embodiment, the thin film stack 25 includes a transparent conductive oxide (TCO) layer 14, an optional resistive transparent buffer layer 16, an n-type layer 18 (e.g., a cadmium sulfide layer), a p-type absorber layer 20 (e.g., a cadmium telluride layer), a back contact layer 22. The n-type layer 18 and the p-type absorber layer 20 generally form a p-n junction 19 in the device 10.

Generally, the reflective color film and its method of application can be used in the formation of any photovoltaic device 10, such as the exemplary device 10 shown in FIG. 1. Although described with respect to the embodiment of FIG. 1, the present disclosure is not intended to be limited to any particular photovoltaic device design. It is contemplated that other photovoltaic device designs can be utilized, including but not limited to monocrystalline silicon, polycrystalline silicon, amorphous silicon, cadmium telluride, copper indium gallium selenide/sulfide, etc.

The exemplary device 10 of FIG. 1 includes a transparent substrate 12 (e.g., glass). In this embodiment, the transparent substrate 12 can be referred to as a “superstrate,” since it is the substrate on which the subsequent layers are formed, but it faces upwards to the radiation source (e.g., the sun) when the thin film photovoltaic device 10 is in used. The transparent substrate 12 can be a high-transmission glass (e.g., high transmission borosilicate glass), low-iron float glass, or other highly transparent glass material. The glass is generally thick enough to provide support for the subsequent film layers (e.g., from about 0.5 mm to about 10 mm thick), and is substantially flat to provide a good surface for forming the subsequent film layers. In one embodiment, the transparent substrate 12 can be a low iron float glass containing less than about 0.15% by weight iron (Fe), and may have a transmission of about 90% or greater in the spectrum of interest (e.g., wavelengths from about 300 nm to about 900 nm).

The transparent conductive oxide (TCO) layer 14 is shown on the inner surface 13 of the transparent substrate 12 of the exemplary device 10. The TCO layer 14 allows light to pass through with minimal absorption while also allowing electric current produced by the device 10 to travel sideways to opaque metal conductors (not shown). For instance, the TCO layer 14 can have a sheet resistance less than about 30 ohm per square, such as from about 4 ohm per square to about 20 ohm per square (e.g., from about 8 ohm per square to about 15 ohm per square). The TCO layer 14 generally includes at least one conductive oxide, such as tin oxide, zinc oxide, or indium tin oxide, or mixtures thereof. Additionally, the TCO layer 14 can include other conductive, transparent materials. The TCO layer 14 can also include zinc stannate and/or cadmium stannate.

The TCO layer 14 can be formed by sputtering, chemical vapor deposition, spray pyrolysis, or any other suitable deposition method. In one particular embodiment, the TCO layer 14 can be formed by sputtering, either DC sputtering or RF sputtering, on the glass 12. For example, a cadmium stannate layer can be formed by sputtering a hot-pressed target containing stoichiometric amounts of SnO₂ and CdO onto the glass 12 in a ratio of about 1 to about 2. The cadmium stannate can alternatively be prepared by using cadmium acetate and tin (II) chloride precursors by spray pyrolysis.

In certain embodiments, the TCO layer 14 can have a thickness between about 0.1 μm and about 1 μm, for example from about 0.1 μm to about 0.5 μm, such as from about 0.25 μm to about 0.45 μm. Suitable flat glass substrates having a TCO layer 14 formed on the superstrate surface can be purchased commercially from various glass manufactures and suppliers. For example, a particularly suitable glass 12 including a TCO layer 14 includes a glass commercially available under the name TEC 15 TCO from Pilkington North America Inc. (Toledo, Ohio), which includes a TCO layer having a sheet resistance of 15 ohms per square.

The resistive transparent buffer layer 16 (RTB layer) is shown on the TCO layer 14 on the exemplary cadmium telluride thin film photovoltaic device 10. The RTB layer 16 is generally more resistive than the TCO layer 14 and can help protect the device 10 from chemical interactions between the TCO layer 14 and the subsequent layers during processing of the device 10. For example, in certain embodiments, the RTB layer 16 can have a sheet resistance that is greater than about 1000 ohms per square, such as from about 10 kOhms per square to about 1000 MOhms per square. The RTB layer 16 can also have a wide optical bandgap (e.g., greater than about 2.5 eV, such as from about 2.7 eV to about 3.0 eV).

Without wishing to be bound by a particular theory, it is believed that the presence of the RTB layer 16 between the TCO layer 14 and the cadmium sulfide layer 18 can allow for a relatively thin cadmium sulfide layer 18 to be included in the device 10 by reducing the possibility of interface defects (i.e., “pinholes” in the cadmium sulfide layer 18) creating shunts between the TCO layer 14 and the cadmium telluride layer 20. Thus, it is believed that the RTB layer 16 allows for improved adhesion and/or interaction between the TCO layer 14 and the cadmium telluride layer 20, thereby allowing a relatively thin cadmium sulfide layer 18 to be formed thereon without significant adverse effects that would otherwise result from such a relatively thin cadmium sulfide layer 18 formed directly on the TCO layer 14.

The RTB layer 16 can include, for instance, a combination of zinc oxide (ZnO) and tin oxide (SnO₂), which can be referred to as a zinc tin oxide layer (“ZTO”). In one particular embodiment, the RTB layer 16 can include more tin oxide than zinc oxide. For example, the RTB layer 16 can have a composition with a stoichiometric ratio of ZnO/SnO₂ between about 0.25 and about 3, such as in about an one to two (1:2) stoichiometric ratio of tin oxide to zinc oxide. The RTB layer 16 can be formed by sputtering, chemical vapor deposition, spraying pryolysis, or any other suitable deposition method. In one particular embodiment, the RTB layer 16 can be formed by sputtering, either DC sputtering or RF sputtering, on the TCO layer 14. For example, the RTB layer 16 can be deposited using a DC sputtering method by applying a DC current to a metallic source material (e.g., elemental zinc, elemental tin, or a mixture thereof) and sputtering the metallic source material onto the TCO layer 14 in the presence of an oxidizing atmosphere (e.g., O₂ gas). When the oxidizing atmosphere includes oxygen gas (i.e., O₂), the atmosphere can be greater than about 95% pure oxygen, such as greater than about 99%.

In certain embodiments, the RTB layer 16 can have a thickness between about 0.075 μm and about 1 μm, for example from about 0.1 μm to about 0.5 μm. In particular embodiments, the RTB layer 16 can have a thickness between about 0.08 μm and about 0.2 μm, for example from about 0.1 μm to about 0.15 μm.

The n-type window layer 18 is shown on resistive transparent buffer layer 16 of the exemplary device 10. The n-type window layer 18 is a n-type layer that includes, in one particular embodiment, cadmium sulfide (CdS) but may also include other materials, such as zinc sulfide, cadmium zinc sulfide, etc., and mixtures thereof as well as dopants and other impurities. For example, the n-type window layer can include cadmium sulfide (i.e., a cadmium sulfide layer), and may further include oxygen up to about 25% by atomic percentage, for example from about 5% to about 20% by atomic percentage. Such a cadmium sulfide layer can have a wide band gap (e.g., from about 2.25 eV to about 2.5 eV, such as about 2.4 eV) in order to allow most radiation energy (e.g., solar radiation) to pass. As such, the n-type window layer 18 is considered a transparent layer on the device 10.

The n-type window layer 18 can be formed by sputtering, chemical vapor deposition, chemical bath deposition, and other suitable deposition methods. In one particular embodiment, the n-type window layer 18 can be formed by sputtering, either direct current (DC) sputtering or radio frequency (RF) sputtering, on the resistive transparent buffer layer 16. Sputtering deposition generally involves ejecting material from a target, which is the material source, and depositing the ejected material onto the substrate to form the film. DC sputtering generally involves applying a voltage to a metal target (i.e., the cathode) positioned near the substrate (i.e., the anode) within a sputtering chamber to form a direct-current discharge. The sputtering chamber can have a reactive atmosphere (e.g., an oxygen atmosphere, nitrogen atmosphere, fluorine atmosphere) that forms a plasma field between the metal target and the substrate. The pressure of the reactive atmosphere can be between about 1 mTorr and about 20 mTorr for magnetron sputtering. When metal atoms are released from the target upon application of the voltage, the metal atoms can react with the plasma and deposit onto the surface of the substrate. For example, when the atmosphere contains oxygen, the metal atoms released from the metal target can form a metallic oxide layer on the substrate. Conversely, RF sputtering generally involves exciting a capacitive discharge by applying an alternating-current (AC) or radio-frequency (RF) signal between the target (e.g., a ceramic source material) and the substrate. The sputtering chamber can have an inert atmosphere (e.g., an argon atmosphere) having a pressure between about 1 mTorr and about 20 mTorr.

Due to the presence of the resistive transparent layer 16, the n-type window layer 18 can have a thickness that is less than about 0.1 μm, such as between about 10 nm and about 100 nm, such as from about 40 nm to about 80 nm, with a minimal presence of pinholes between the resistive transparent layer 16 and the n-type window layer 18. Additionally, a n-type window layer 18 having a thickness less than about 0.1 μm reduces any adsorption of radiation energy by the n-type window layer 18, effectively increasing the amount of radiation energy reaching the underlying cadmium telluride layer 20.

The p-type absorber layer 20 is shown on the n-type window layer 18 in the exemplary thin film photovoltaic device 10 of FIG. 1. The p-type absorber layer 20 generally, in one particular embodiment, includes cadmium telluride (CdTe) but may also include other materials (also referred to as a cadmium telluride layer). As the p-type absorber layer of device 10, the cadmium telluride layer 20 is the photovoltaic layer that interacts with the cadmium sulfide layer 18 (i.e., when utilized as the n-type layer) to produce current from the adsorption of radiation energy by absorbing the majority of the radiation energy passing into the device 10 due to its high absorption coefficient and creating electron-hole pairs. For example, the cadmium telluride layer 20 can generally be formed from cadmium telluride and can have a bandgap tailored to absorb radiation energy (e.g., from about 1.4 eV to about 1.5 eV, such as about 1.45 eV) to create the maximum number of electron-hole pairs with the highest electrical potential (voltage) upon absorption of the radiation energy. Electrons may travel from the p-type side (i.e., the cadmium telluride layer 20) across the junction to the n-type side (i.e., the cadmium sulfide layer 18) and, conversely, holes may pass from the n-type side to the p-type side. Thus, the p-n junction formed between the cadmium sulfide layer 18 and the cadmium telluride layer 20 forms a diode in which the charge imbalance leads to the creation of an electric field spanning the p-n junction. Conventional current is allowed to flow in only one direction and separates the light induced electron-hole pairs.

The cadmium telluride layer 20 can be formed by any known process, such as vapor transport deposition, chemical vapor deposition (CVD), spray pyrolysis, electro-deposition, sputtering, close-space sublimation (CSS), etc. In one particular embodiment, the cadmium sulfide layer 18 is deposited by a sputtering and the cadmium telluride layer 20 is deposited by close-space sublimation. In particular embodiments, the cadmium telluride layer 20 can have a thickness between about 0.1 μm and about 10 μm, such as from about 1 μm and about 5 μm. In one particular embodiment, the cadmium telluride layer 20 can have a thickness between about 2 μm and about 4 μm, such as about 3 μm.

A series of post-forming treatments can be applied to the exposed surface of the cadmium telluride layer 20. These treatments can tailor the functionality of the cadmium telluride layer 20 and prepare its surface for subsequent adhesion to the back contact layers, particularly the conductive paste layer 23. For example, the cadmium telluride layer 20 can be annealed at elevated temperatures (e.g., from about 350° C. to about 500° C., such as from about 375° C. to about 424° C.) for a sufficient time (e.g., from about 1 to about 10 minutes) to create a quality p-type absorber layer of cadmium telluride. Without wishing to be bound by theory, it is believed that annealing the cadmium telluride layer 20 (and the device 10) converts the weakly p-type cadmium telluride layer 20 to a more strongly p-type cadmium telluride layer 20 having a relatively low resistivity. Additionally, the cadmium telluride layer 20 can recrystallize and undergo grain growth during annealing.

Annealing the cadmium telluride layer 20 can be carried out in the presence of cadmium chloride in order to dope the cadmium telluride layer 20 with chloride ions. For example, the cadmium telluride layer 20 can be washed with an aqueous solution containing cadmium chloride then annealed at the elevated temperature.

In one particular embodiment, after annealing the cadmium telluride layer 20 in the presence of cadmium chloride, the surface can be washed to remove any cadmium oxide formed on the surface. This surface preparation can leave a Te-rich surface on the cadmium telluride layer 20 by removing oxides from the surface, such as CdO, CdTeO₃, CdTe₂O₅, etc. For instance, the surface can be washed with a suitable solvent (e.g., ethylenediamine also known as 1,2 diaminoethane or “DAE”) to remove any cadmium oxide from the surface. In one embodiment, the application of the treatment solution described above, and its subsequent annealing, can be performed after annealing the cadmium telluride layer 20 in the presence of cadmium chloride and washing the surface 21.

The back contact 22 serves as the opposite electrode to the transparent conductive oxide layer 12. In one embodiment, the back contact 22 can be formed from a conductive paste layer (e.g., a graphite layer) and/or a metal contact layer. The back contact 22 is formed on, and in one embodiment is in direct contact with, the cadmium telluride layer 20.

Other layers may also be present in the thin film stack, although not specifically shown in the embodiment of FIG. 1. For example, index matching layers may be present between the transparent conductive oxide layer 14 and the superstrate 12. Additionally, an oxygen getter layer may be present in the thin film stack, such as adjacent to the transparent conductive oxide layer 14 (e.g., between the transparent conductive oxide layer 14 and the optional resistive transparent buffer layer 16).

Other components (not shown) can be included in the exemplary device 10, such as buss bars, external wiring, laser etches, etc. For example, when the device 10 forms a photovoltaic cell of a photovoltaic module, a plurality of photovoltaic cells can be connected in series in order to achieve a desired voltage, such as through an electrical wiring connection. Each end of the series connected cells can be attached to a suitable conductor such as a wire or bus bar, to direct the photovoltaically generated current to convenient locations for connection to a device 10 or other system using the generated electric. A convenient means for achieving such series connections is to laser scribe the device 10 to divide the device 10 into a series of cells connected by interconnects. In one particular embodiment, for instance, a laser can be used to scribe the deposited layers of the semiconductor device 10 to divide the device 10 into a plurality of series connected cells, as described above with respect to FIG. 1.

An encapsulating substrate 24 is laminated to the transparent substrate 12 to complete the device 10.

Methods for forming a photovoltaic device 10 and/or an array, such as described above, are also generally provided.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A thin film photovoltaic device, comprising:
a transparent substrate defining an inner surface and an outer surface;
a thin film stack on the inner surface of the transparent substrate, wherein the thin film stack comprises a photovoltaic heterojunction;
an encapsulation substrate on the thin film stack; and
a color reflection film on the outer surface of the transparent substrate, wherein the color reflection film comprises a colorant.

2. The thin film photovoltaic device as in claim 1, wherein the colorant comprises a refractive material.

3. The thin film photovoltaic device as in claim 2, wherein the refractive material comprises a nitride material.

4. The thin film photovoltaic device as in claim 3, wherein the nitride material comprises Si₃N₄.

5. The thin film photovoltaic device as in claim 2, wherein the refractive material comprises an oxide material.

6. The thin film photovoltaic device as in claim 5, wherein the oxide material comprises TiO₂.

7. The thin film photovoltaic device as in claim 2, wherein the color reflective film defines a thin film on the outer surface of the transparent substrate.

8. The thin film photovoltaic device as in claim 7, wherein the refractive material is dispersed within a transparent oxide.

9. The thin film photovoltaic device as in claim 8, wherein the transparent oxide comprises tin oxide, zinc oxide, silicon dioxide, or mixtures thereof.

10. The thin film photovoltaic device as in claim 1, wherein the colorant is dispersed within a transparent polymeric binder.

11. The thin film photovoltaic device as in claim 1, wherein the color reflective film is substantially uniform on the outer surface of the transparent substrate.

12. The thin film photovoltaic device as in claim 1, wherein the color reflective film defines a pattern on the outer surface of the transparent substrate.

13. The thin film photovoltaic device as in claim 1, wherein the color reflective film has a thickness of about 10 nm to about 5 μm.

14. The thin film photovoltaic device as in claim 1, wherein multiple color reflective films are present on the outer surface, each color reflective film defining a pattern on the outer surface of the transparent substrate.

15. The thin film photovoltaic device as in claim 1, wherein the color reflective film also serves as an antireflection coating on the outer surface.

16. A method of forming an image on an array of photovoltaic modules, the method comprising:
creating a digital image on a computing device;
overlaying the digital image on a digital representation of a solar array to generate an image map, wherein the digital representation of the solar array comprises a plurality of array segments that each correspond to an individual photovoltaic device;
forming a color reflection film on an outer surface of the individual photovoltaic devices using the image map such that the color reflection film on each individual photovoltaic device corresponds to one of the array segments of the digital representation of the solar array; and
arranging the individual photovoltaic devices into an array such that the image is formed by the collective photovoltaic devices.

17. The method as in claim 16, wherein a first portion of the image is formed by a first portion of the color reflection film deposited on a first photovoltaic device, and wherein a second portion of the image is formed by a second portion of the color reflection film deposited on a second photovoltaic device.

18. The method as in claim 16, wherein the first photovoltaic device is adjacent to the second photovoltaic device.

19. The method as in claim 17, wherein a third portion of the image is formed by a third portion of the color reflection film deposited on a third photovoltaic device, and wherein a fourth portion of the image is formed by a fourth portion of the color reflection film deposited on a fourth photovoltaic device.

20. An array of photovoltaic modules having different colors, the array of photovoltaic modules comprising:
at least two photovoltaic module comprising
a transparent substrate defining an inner surface and an outer surface;
a thin film stack on the inner surface of the transparent substrate, wherein the thin film stack comprises a photovoltaic heterojunction;
an encapsulation substrate on the thin film stack; and
a color reflection film on the outer surface of the transparent substrate, wherein the color reflection film comprises a colorant;
wherein the photovoltaic modules are arranged in a manner so that the array forms a recognizable pattern.
